(19) United States
(12) Patent Application Publication
(10) Pub. No.: US 2025/0391767 A1
(43) Pub. Date: Dec. 25, 2025

(54) THREE-TERMINAL CELL WITH MULTI-LEVEL FERROELECTRIC MEMORY IN THE BACK-END-OF-LINE

(71) Applicant: International Business Machines Corporation, Armonk, NY (US)

(72) Inventors: Donato Francesco Falcone, Zurich (CH); Antonio La Porta, Kilchberg (CH); Laura Bégon-Lours, Paris (FR); Bert Jan Offrein, Schoenenberg (CH)

(21) Appl. No.: 18/754,074

(22) Filed: Jun. 25, 2024

(51) Int. Cl. H01L 23/528; G11C 5/06; G11C 11/22; H01L 29/66; H01L 29/78; H10B 51/30

(52) U.S. Cl. CPC H01L 23/5283; G11C 5/063; G11C 11/2273; G11C 11/2275; H01L 23/5286; H10B 51/30; H10D 30/0415; H10D 30/701

(57) ABSTRACT

Three-terminal, multi-level non-volatile memory cells having a FeFET in the BEOL are provided. In one aspect, a memory cell includes: a cascade of elements all sharing a common gate terminal and, via the common gate terminal, a common V_{G}, where the cascade of elements includes: an nMOS FET; an ox-FeFET located in the BEOL that is connected to the nMOS FET; and a pMOS FET that is connected to the ox-FeFET. Multi-cell memory implementations thereof, and methods for operating the present memory cells are also provided.

### BACKGROUND

The present invention generally relates to integrated circuits such as complementary metal oxide semiconductor (CMOS) integrated circuits, and, more particularly, to non-volatile ferroelectric memory cells, and multi-cell memory implementations thereof.

The memory hierarchy in today's integrated circuits generally includes memory at three levels. For instance, at one level, volatile memory such as static random access memory (SRAM) is placed on-chip and close to processing circuits. At another level, a larger amount of volatile memory such as dynamic random access memory (DRAM) is placed off-chip in discrete dies. At yet another level, main storage is provided as non-volatile memory such as Flash memory and is available off-chip as discrete components.

Functionality advancements in modern CMOS technology typically focus on shrinking the process node to increase the number of transistors and their computational power and energy efficiency, and adding more local memory closely with processing units to improve latency, bandwidth, efficiency, and cost. Doing so, however, involves making tradeoffs between speed and cost on one hand and capacity on the other. For instance, on-chip, high performance and low latency memories like SRAM show poor cost effectiveness and low density, while off-chip, high density and cost-effective memories like Flash memory show low performance and endurance.

### BRIEF SUMMARY

Principles of the invention provide three-terminal, multi-level non-volatile memory cells having a ferroelectric field-effect transistor (FeFET) in the back-end-of-line (BEOL), and multi-cell memory implementations thereof. In one aspect, a memory cell is provided. The memory cell includes: a cascade of elements all sharing a common gate terminal and, via the common gate terminal, a common gate voltage V_{G}, where the cascade of elements includes: an n-doped metal oxide semiconductor (nMOS) FET; an oxide-ferroelectric FET (ox-FeFET) located in a Back-End-of-Line (BEOL) that is connected to the nMOS FET; and a p-doped metal oxide semiconductor (pMOS) FET that is connected to the ox-FeFET.

The memory cell can further include: a top electrode terminal; and a ground terminal, where the nMOS FET is connected to the ox-FeFET and to the ground terminal, and where the pMOS FET is connected to the ox-FeFET and to the top electrode terminal. The ox-FeFET can include: an oxide channel or ox-channel (e.g., tungsten oxide (WOₓ), tantalum oxide (TaOₓ), titanium oxide (TiOₓ), indium gallium zinc oxide (IGZO), copper oxide (Cu₂O), nickel oxide (NiO) and/or tin oxide (SnO)); a ferroelectric material (e.g., a hafnium oxide (HfO₂)-based material) disposed on the ox-channel; and a metal gate disposed on the ferroelectric material, where the metal gate is connected to the common gate terminal. Alternatively, ox-FeFET can include: a metal gate connected to the common gate terminal; a ferroelectric material disposed on the metal gate; and an oxide channel disposed on the ferroelectric material.

In another aspect, a multi-cell memory device is provided. The multi-cell memory device includes: bit lines; source lines oriented orthogonal to the bit lines, where the bit lines and the source lines define a set of rows and columns of the multi-cell memory device; word lines oriented diagonal to the bit lines and the source lines; and a plurality of memory cells interconnected by the bit lines, source lines and word lines, where the plurality of memory cells each includes a cascade of elements all sharing a common gate terminal and, via the common gate terminal, a common gate voltage V_{G}, and where the cascade of elements includes: an n-doped metal oxide semiconductor (nMOS) field-effect transistor (FET), an oxide-ferroelectric FET (ox-FeFET) located in a Back-End-of-Line (BEOL) that is connected to the nMOS FET and a p-doped metal oxide semiconductor (pMOS) FET that is connected to the ox-FeFET. The word lines can be located in at least two different metal levels of the multi-cell memory device.

In yet another aspect, a method is provided. The method includes: providing a memory cell having a cascade of elements all sharing a common gate terminal, where the cascade of elements includes: an nMOS FET, an ox-FeFET located in a BEOL, and a pMOS FET, and where the nMOS FET is connected to the ox-FeFET and to a ground terminal, and where the pMOS FET is connected to the ox-FeFET and to a top electrode terminal; and controlling a top electrode voltage (V_{TE}) applied to the top electrode terminal and a gate voltage (V_{G}) applied to the common gate terminal to perform multi-level programming of the memory cell.

For instance, the nMOS FET can be turned ON, and the pMOS FET can be turned OFF to program a state where a net polarization of a ferroelectric material of the ox-FeFET points toward an oxide channel of the ox-FeFET. Alternatively, the nMOS FET can be turned OFF, and the pMOS FET can be turned ON to program a state where a net polarization of a ferroelectric material of the ox-FeFET points away from an oxide channel of the ox-FeFET. Once programmed, the nMOS FET can be turned ON, and the pMOS FET can be turned ON to read information stored in the memory cell.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 depicts a circuit diagram of the present memory cell according to aspects of the invention;

FIG. 2 is a cross-sectional schematic of an exemplary memory cell with a ferroelectric field-effect transistor (FeFET) having a top-gated design according to aspects of the invention;

FIG. 3 is a cross-sectional schematic of an exemplary memory cell with a FeFET having a back-gated design according to aspects of the invention;

FIGS. 4A-B illustrate an example of how ferroelectric polarization screening leads to accumulation/depletion of carriers (i.e., electrons) in an n-type oxide-channel (ox-channel) according to aspects of the invention;

FIGS. 5A-B illustrate an example of how ferroelectric polarization screening leads to accumulation/depletion of carriers (i.e., holes) in a p-type ox-channel according to aspects of the invention;

FIGS. 6-8 illustrate the writing of a multi-level state where the net polarization P of the ferroelectric material points toward the ox-channel according to aspects of the invention;

FIGS. 9-11 illustrate the writing of a multi-level state where the net polarization P of the ferroelectric material points away from the ox-channel according to aspects of the invention;

FIGS. 12-14 illustrate the reading of information stored in the memory cell according to aspects of the invention; and

FIGS. 15-19 illustrate implementations of the present memory cells in an exemplary multi-cell memory device having a crossbar architecture according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary memory cell (e.g., memory cell 100, 200, 300, 600, 900, 1200, 1500, etc.) is provided having a cascade of elements all sharing a common gate (G) terminal and, via the common gate (G) terminal, a common gate voltage V_{G}. The cascade of elements includes an nMOS FET (e.g., nMOS FET 102, 602, 902, 1202, 1502, etc.), an ox-FeFET (e.g., ox-FeFET 104, 104′, 104″, 604, 904, 1204, 1504, etc.) located in a BEOL that is connected to the nMOS FET, and a pMOS FET (e.g., pMOS FET 106, 606, 906, 1206, 1506, etc.) that is connected to the ox-FeFET.

Optionally, the memory cell (e.g., memory cell 100, 200, 300, 600, 900, 1200, 1500, etc.) can further include: a top electrode (TE) terminal; and a ground (GND) terminal. For example, the nMOS FET (e.g., nMOS FET 102, 602, 902, 1202, 1502, etc.) can be connected to the ox-FeFET (e.g., ox-FeFET 104, 104′, 104″, 604, 904, 1204, 1504, etc.) and to the GND terminal, and the pMOS FET (e.g., pMOS FET 106, 606, 906, 1206, 1506, etc.) can be connected to the ox-FeFET and to the TE terminal.

Also, optionally, the ox-FeFET (e.g., ox-FeFET 104′) can include an ox-channel (e.g., ox-channel 104b′), a ferroelectric material (e.g., ferroelectric material 104a′) disposed on the ox-channel, and a metal gate (e.g., metal gate 104c′) disposed on the ferroelectric material, with the metal gate being connected to the common gate (G) terminal. Alternatively, ox-FeFET (e.g., ox-FeFET 104″) can include: a metal gate (e.g., metal gate 104c″) connected to the common gate (G) terminal; a ferroelectric material (e.g., ferroelectric material 104a″) disposed on the metal gate; and an oxide channel (e.g., ox-channel 104b″) disposed on the ferroelectric material.

In another aspect, an exemplary multi-cell memory device is provided. The multi-cell memory device includes bit lines (i.e., BL₁, BL₂, BL₃, etc.), source lines (i.e., SL₁, SL₂, SL₃, etc.) oriented orthogonal to the bit lines with the bit lines and the source lines defining a set of rows and columns of the multi-cell memory device, word lines (i.e., WL₁, WL₂, WL₃, etc.) oriented diagonal to the bit lines and the source lines, and a plurality of memory cells (e.g., memory cells 1500) interconnected by the bit lines, source lines and word lines, where the plurality of memory cells each includes a cascade of elements all sharing a common gate (G) terminal and, via the common gate (G) terminal, a common gate voltage V_{G}. The cascade of elements includes an nMOS FET (e.g., nMOS FET 1502), an ox-FeFET (e.g., ox-FeFET 1504) located in a BEOL that is connected to the nMOS FET and a pMOS FET (e.g., pMOS FET 1506) that is connected to the ox-FeFET.

Optionally, the word lines (i.e., WL₁, WL₂, WL₃, etc.) can be located in at least two different metal levels of the multi-cell memory device. For instance, the word lines (i.e., WL₁, WL₂, WL₃, etc.) can include first metal lines (e.g., first metal lines 1512a,b,c,d,e,etc.) located in a first metal level and oriented orthogonal to second metal lines (e.g., second metal lines 1514a,b,etc.) located in a second metal level.

In yet another aspect, a method is provided whereby, a memory cell (e.g., memory cell 600) having a cascade of elements all sharing a common gate (G) terminal is provided. The cascade of elements includes nMOS FET (e.g., nMOS FET 602), an ox-FeFET (e.g., ox-FeFET 604) located in a BEOL, and a pMOS FET (e.g., pMOS FET 606), and where the nMOS FET is connected to the ox-FeFET and to a ground (GND) terminal, and where the pMOS FET is connected to the ox-FeFET and to a top electrode (TE) terminal. A top electrode voltage (V_{TE}) applied to the top electrode (TE) terminal and a gate voltage (V_{G}) applied to the common gate (G) terminal are controlled to perform multi-level programming of the memory cell.

For instance, in an exemplary methodology 700, a memory cell (e.g., memory cell 600) is provided (in step 702), the nMOS FET (e.g., nMOS FET 602) can be turned ON (in step 704), and the pMOS FET (e.g., pMOS FET 606) can be turned OFF (in step 706) to program a state where a net polarization of a ferroelectric material (e.g., ferroelectric material 604a) of the ox-FeFET (e.g., ox-FeFET 604) points toward an oxide channel (e.g., ox-channel 604b) of the ox-FeFET.

Alternatively, in an exemplary methodology 1000, a memory cell (e.g., memory cell 900) is provided (in step 1002), the nMOS FET (e.g., nMOS FET 902) can be turned OFF (in step 1004), and the pMOS FET (e.g., pMOS FET 906) can be turned ON (in step 1006) to program a state where a net polarization of a ferroelectric material (e.g., ferroelectric material 904a) of the ox-FeFET (e.g., ox-FeFET 904) points away from an oxide channel (e.g., ox-channel 904b) of the ox-FeFET.

In an exemplary methodology 1300, a programmed memory cell (e.g., memory cell 1200) is provided (in step 1302), the nMOS FET (e.g., nMOS FET 1202) can be turned ON (in step 1304), and the pMOS FET (e.g., pMOS FET 1206) can be turned ON (in step 1306) to read information stored in the memory cell.

Techniques as disclosed herein can provide substantial beneficial technical effects. Some embodiments may not have these potential advantages and these potential advantages are not necessarily required of all embodiments. By way of example only and without limitation, one or more embodiments of the present three-terminal 1T1Fe1T with ferroelectric non-volatile memory integrated in the Back-end-of-Line (BEOL) can provide one or more of:
Efficient and effective techniques for adding memory functionalities in the BEOL, as opposed to standard Front-End-of-Line (FEOL) implementations and the constraints associated therewith such as FEOL thermal budget and device geometry limitations;
Enhanced memory density by way of the present multi-level memory design which enables addressing, for example, up to 200 levels per cell;
Improved the energy efficiency and endurance of the current non-volatile state of the art memory, such as Flash memory, by more than two orders of magnitude;
Effective high performance, low latency and cost-effective non-volatile memory;
Multi-bit implementations that provide access to and programming of individual memory cells, without cross-talk; and
Increased integration density with a lower requirement for interconnects as compared to conventional four-terminal memory cells.

In ferroelectric-based memory cells, such as ferroelectric field-effect transistors (FeFETs), data is stored based on the resistive state of a ferroelectric material. Different resistive states can be achieved using an applied electric field, and are based on the polarization of ferroelectric domains (i.e., regions of the ferroelectric material having dipole moments of the same orientation).

Semiconductor manufacturing of integrated circuit chips can generally be subdivided into two main blocks, the Front-End-of-Line (FEOL) and the Back-End-of-Line (BEOL). The FEOL typically covers the processing of active components of the chips such as transistors, while the BEOL refers to the passive interconnects that reside in the upper regions of the chips such as wires. Accordingly, many standard implementations employ FeFETs in the FEOL. Doing so, however, brings about some notable limitations. For instance, FEOL FeFET implementations generally use silicon (Si) as a channel, which is not an option in the BEOL due to deposition and thermal constraints. However, the charge trapping effect of Si-based FeFETs can undesirably lead to poor reliability and limit programming speed. Further, the FEOL is constrained in terms of device area. With FeFETs, a smaller device area leads to a smaller number of ferroelectric domains. Fewer ferroelectric domains results in only limited multi-level switching.

Relocating the FeFETs to the less crowded BEOL is advantageous in terms of increasing the device area to provide a larger number of ferroelectric domains, and thereby enhanced multi-level switching, e.g., more than 200 resistance values. The BEOL also provides more flexibility on the channel material choice. For instance, oxide channel materials such as tungsten oxide (WOₓ) can be deposited in the BEOL, and can be used as the channel material in BEOL FeFET technology. However, passive BEOL FeFET memory architectures suffer from crosstalk amongst memory cells.

With that in mind, one or more embodiments presented herein advantageously provide a non-volatile, three-terminal, multi-level FeFET-based memory cell in the BEOL. As highlighted above, locating the FeFET in the BEOL desirably relaxes area constraints. And as such, a larger device area permits a larger number of ferroelectric domains in the FeFET thereby enhancing the multi-level switching capabilities. As will be described in detail below, the ferroelectric partial polarization switching of the present FeFET allows for addressing the resistive levels of multiple channels. Further, embodiments are contemplated herein where the present memory cell employs an oxide channel FeFET (ox-FeFET). Use of an oxide channel advantageously improves reliability and programming speed (e.g., less than 20 nanoseconds) by, as highlighted above, avoiding the charge trapping effect of Si-based FeFETs.

As will be described in detail below, the present memory cells preferably employ a cascade architecture with a connected series of elements, including the FeFET located in the BEOL. Namely, embodiments are contemplated herein where each memory cell includes the following elements: one n-doped metal oxide semiconductor (nMOS) field-effect transistor (FET) in the FEOL (1T), one (oxide channel) FeFET in the BEOL (1Fc), and one p-doped metal oxide semiconductor (pMOS) FET in the FEOL (1T) (also abbreviated herein as “1T1Fe1T”). These elements are connected in series, i.e., cascaded, and all share the same gate voltage. The resulting 1T1Fe1T non-volatile memory cell has three terminals. Cascading the memory cell elements in this manner enables placement of (in this case an active rather than passive) FeFET in the BEOL without encountering crosstalk amongst adjacent memory cells.

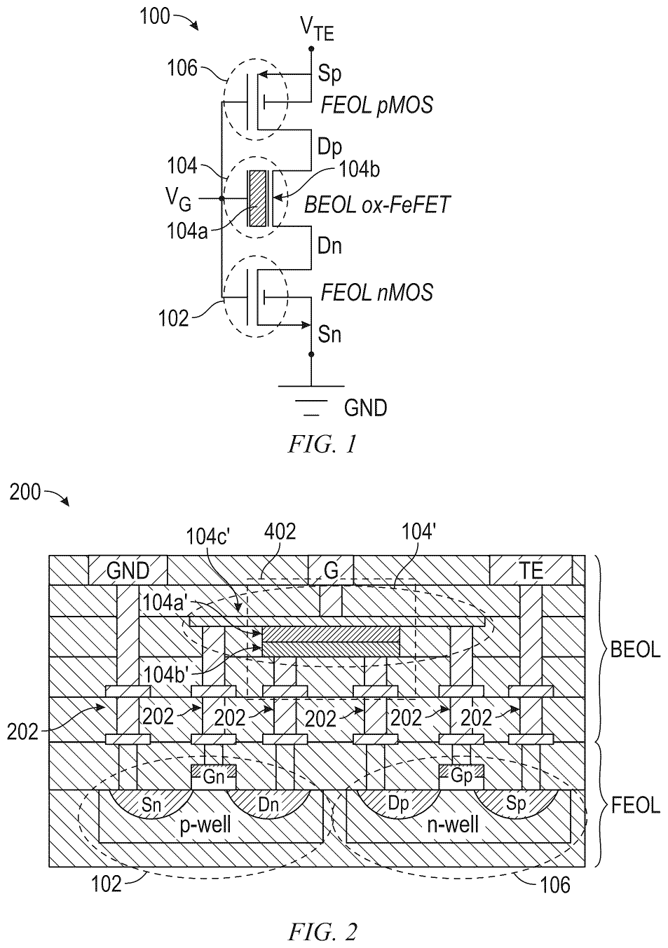

For instance, referring to the circuit diagram provided in FIG. 1, the present memory cell 100 includes a cascade of three elements. Namely, in no particular order, the first element is an nMOS FET 102. According to an exemplary embodiment, the nMOS FET 102 is located in the FEOL. The second element is an ox-FeFET 104 located in the BEOL that is connected to the nMOS FET 102. The third element is a pMOS FET 106 that is connected to the ox-FeFET 104. According to an exemplary embodiment, like nMOS FET 102, the pMOS FET 106 is also located in the FEOL.

More specifically, as shown in FIG. 1, a drain of the nMOS FET 102 (Dn) and a source of the nMOS FET 102 (Sn) are connected to the ox-FeFET 104 and to a ground (GND) terminal, respectively. A drain of the pMOS FET 106 (Dp) and a source of the pMOS FET 106 (Sp) are connected to the ox-FeFET 104 and to a top electrode (TE) terminal, respectively. Notably, as shown in FIG. 1, all three of the cascaded elements (i.e., the nMOS FET 102, the ox-FeFET 104, and the pMOS FET 106) preferably share the same common gate voltage (V_{G}) applied to a common gate (G) terminal.

Thus, the resulting memory cell 100 has three independent terminals: the TE, G, and GND. As will be described in detail below, sweeping the TE voltage (V_{TE}) and the V_{G} accordingly allows for multi-level programming of the memory cell 100, to where a polarization P of a ferroelectric material 104a of the ox-FeFET 104 points either toward or away from an oxide channel 104b (or ox-channel) of the ox-FeFET 104.

In one exemplary embodiment, the ox-FeFET has a top-gated design. Sec, for example, ox-FeFET 104′ in memory cell 200 of FIG. 2. By ‘top-gated’ it is meant that a metal gate 104c′ (connected to the gate (G) terminal common to nMOS FET 102, ox-FeFET 104′, and pMOS FET 106) is disposed on top of a ferroelectric material 104a′ which in turn is disposed on an ox-channel 104b′ of the ox-FeFET 104′.

Consistent with the design considerations highlighted above, memory cell 200 includes three cascaded elements, i.e., nMOS FET 102 in the FEOL, ox-FeFET 104′ in the BEOL, and pMOS FET 106 in the FEOL, forming the present 1T1Fe1T memory cell configuration. In the same manner as described above, the drain of the nMOS FET 102 (Dn) and a source of the nMOS FET 102 (Sn) are connected to the ox-FeFET 104′ and to the GND terminal, respectively, via interconnects 202. A drain of the pMOS FET 106 (Dp) and a source of the pMOS FET 106 (Sp) are connected to the ox-FeFET 104′ and to the TE terminal, respectively, via the interconnects 202. Notably, as shown in FIG. 2, the gate (G) terminal is connected directly to the metal gate 104c′ of ox-FeFET 104′ and, via the interconnects 202, the metal gate 104c′ is connected to both a gate of the nMOS FET 102 (Gn) and a gate of the pMOS FET 106 (Gp). Thus, all three of the cascaded elements (i.e., the nMOS FET 102, the ox-FeFET 104′, and the pMOS FET 106) can share the same V_{G} applied to the gate (G) terminal. The resulting memory cell 200 has three independent terminals: the TE, G, and GND. Notably, since the ox-FeFET 104′ is located in the BEOL, the ox-FeFET 104′ is present amongst the interconnects 202 that, as shown in FIG. 2, link the ox-FeFET 104′ to both the nMOS FET 102 and the pMOS FET 106.

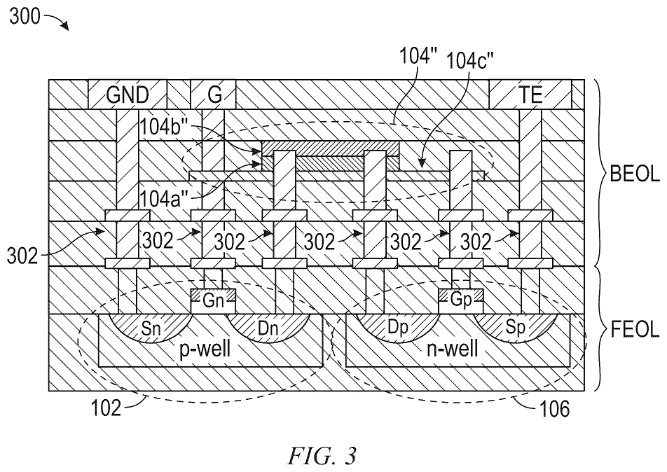

In another exemplary embodiment, the ox-FeFET has a back-gated design. See, for example, ox-FeFET 104″ in memory cell 300 of FIG. 3. By ‘back-gated’ it is meant that an ox-channel 104b″ of the ox-FeFET 104″ is disposed on top of a ferroelectric material 104a″ which in turn is disposed on a metal gate 104c″ (connected to the gate (G) terminal common to nMOS FET 102, ox-FeFET 104″, and pMOS FET 106).

Again, consistent with the design considerations highlighted above, memory cell 300 includes three cascaded elements, i.e., nMOS FET 102 in the FEOL, ox-FeFET 104″ in the BEOL, and pMOS FET 106 in the FEOL, forming the present 1T1Fe1T memory cell configuration. Here as well, the drain of the nMOS FET 102 (Dn) and a source of the nMOS FET 102 (Sn) are connected to the ox-FeFET 104″ and to the GND terminal, respectively, via interconnects 302. A drain of the pMOS FET 106 (Dp) and a source of the pMOS FET 106 (Sp) are connected to the ox-FeFET 104″ and to the TE terminal, respectively, via the interconnects 302. Notably, as shown in FIG. 3, the gate (G) terminal is connected directly to the metal gate 104c″ of ox-FeFET 104″ and, via the interconnects 302, the metal gate 104c″ is connected to both a gate of the nMOS FET 102 (Gn) and a gate of the pMOS FET 106 (Gp). Thus, all three of the cascaded elements (i.e., the nMOS FET 102, the ox-FeFET 104″, and the pMOS FET 106) can share the same V_{G} applied to the gate (G) terminal. As above, the resulting memory cell 300 has three independent terminals: the TE, G, and GND. Notably, since the ox-FeFET 104″ is located in the BEOL, the ox-FeFET 104″ is present amongst the interconnects 302 that, as shown in FIG. 3, link the ox-FeFET 104″ to both the nMOS FET 102 and the pMOS FET 106.

Suitable ferroelectric materials 104a, 104a′, 104a″, etc. include, but are not limited to, hafnium oxide (HfO₂)-based materials such as pure HfO₂, hafnium zirconate (Hf_{-0.5}Zr_{-0.5}O₂), and/or HfO₂ doped with small quantities of nitrogen (N), carbon (C), silicon (Si), aluminum (Al), lanthanum (La), gadolinium (Gd), yttrium (Y), scandium (Sc), and/or strontium (Sr) (whereby dopants such as Si, Al and La raise the crystallization temperature of the HfO₂ thereby increasing the thermal stability). By way of example only, for X-doped HfO₂ where X is a metal (i.e., Al, La, Gd, Sc and/or Sr) or Si, an ion percentage [X]/([Hf]+[X]) of less than about 10%, e.g., from about 2% to about 6% and ranges therebetween is considered a small dopant quantity. Similarly, when X is N or C, an ion percentage [X]/([O]+[X]) of less than about 10%, e.g., from about 2% to about 6% and ranges therebetween is considered a small dopant quantity. According to an exemplary embodiment, the ferroelectric material 104a, 104a′, 104a″, etc. has a thickness of from about 5 nanometers (nm) to about 15 nm, e.g., about 10 nm.

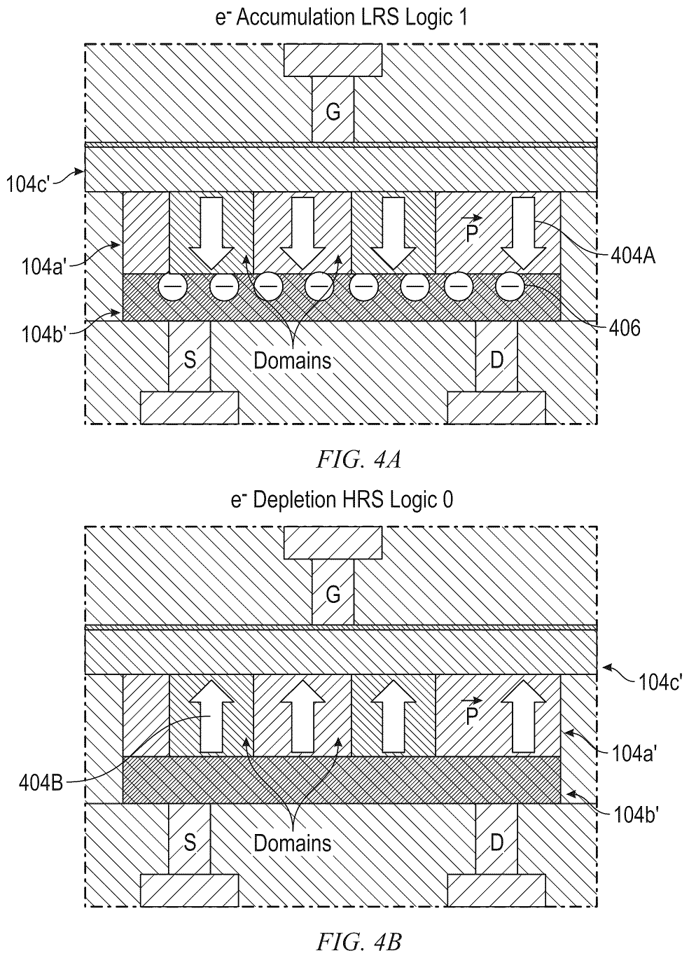

The ox-channel 104b, 104b′, 104b″, etc. is formed from an oxide semiconductor material with Ohmic conduction which, according to an exemplary embodiment, can be either an n-type semiconductor such as, but not limited to, tungsten oxide (WOₓ), tantalum oxide (TaOₓ), titanium oxide (TiOₓ) and/or indium gallium zinc oxide (IGZO) where x is an integer or a portion of a number or a p-type semiconductor such as, but not limited to, copper oxide (Cu₂O), nickel oxide (NiO) and/or tin oxide (SnO). Ferroelectric polarization screening leads to accumulation/depletion of carriers in the ox-channel 104b, 104b′, 104b″, etc. With an n-type semiconductor, electrons (e⁻) serve as the main charge carrier to screen the ferroelectric polarization P. See, for example, FIG. 4A and FIG. 4B. For illustrative purposes only, FIG. 4A and FIG. 4B depict the above-described top-gated FeFET design (specifically a region of the memory cell 200 within dashed box 402 in FIG. 2). Although one skilled in the art would appreciate that the same basic principles also apply to the aforementioned back-gated design.

Specifically, in the example depicted in FIG. 4A, the ox-channel 104b′ shown is an n-type semiconductor. Arrows 404A illustrate a scenario where the ox-FeFET 104′ is programmed such that a net polarization P of the corresponding ferroelectric material 104a′ points toward the ox-channel 104b′, resulting in an e accumulation in the ox-channel 104b′ (as indicated by ‘-’ symbols 406). As highlighted above, a ferroelectric material has regions (i.e., domains) of homogeneous polarization, namely a polarization that points in the same direction. However, the polarization of adjacent domains can point in a different direction. Thus, absent an electric field, the net polarization P of the ferroelectric material 104a′ is initially zero. Applying an electric field to the ferroelectric material 104a′ changes the net polarization.

By controlling the net polarization of the ferroelectric material 104a′, the resistance states of the memory cell 200 can be divided into low resistance states (LRS) and high resistance states (HRS) based on the conductivity of the ox-channel 104b′. Experimental evidence has shown that memory cell 200 can store more than 200 resistance values (multi-state device), which can be mapped to a memory data state. For instance, according to an exemplary embodiment, the scenario illustrated in FIG. 4A is one where electrons e″ are the main charge carriers and the polarization P of the ferroelectric material 104a′ points toward the ox-channel 104b′ resulting in an accumulation of electrons e, and therefore multi-logic ‘1’ resistance levels (LRS).

FIG. 4B depicts the scenario with an n-type semiconductor for the ox-channel 104b′ where the polarization P of the ferroelectric material 104a′ points away from the ox-channel 104b′. See arrows 404B. This results in depletion of the main charge carriers in the ox-channel 104b′ (electrons e⁻), and therefore multi-logic ‘0’ resistance levels (HRS).

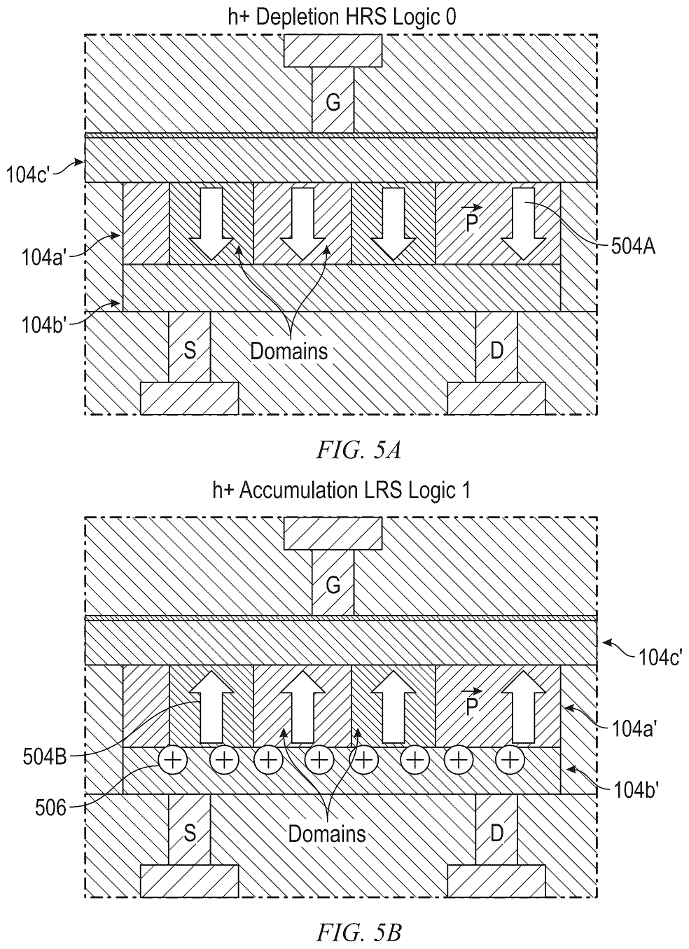

Alternatively, in the example depicted in FIGS. 5A and 5B, the ox-channel 104b′ shown is a p-type semiconductor. With a p-type semiconductor, holes (h⁺) serve as the main charge carriers to screen the ferroelectric polarization P. As with the previous example, FIG. 5A and FIG. 5B depict the region of the memory cell 200 within dashed box 402 in FIG. 2 having a top-gated FeFET design. Although one skilled in the art would appreciate that the same basic principles also apply to the aforementioned back-gated design.

Specifically, in the example depicted in FIG. 5A, arrows 504A illustrate a scenario where the ox-FeFET 104′ is programmed such that a net polarization P of the corresponding ferroelectric material 104a′ points toward the ox-channel 104b′, resulting in the depletion of the main charge carriers (holes h⁺) in the ox-channel 104b′. According to an exemplary embodiment, the scenario illustrated in FIG. 5A is one where holes h⁺ are the main charge carriers and the polarization P of the ferroelectric material 104a′ points toward the ox-channel 104b′ resulting in a depletion of the main charge carriers (holes h⁺) in the ox-channel 104b′, and therefore multi-logic ‘0’ resistance levels (HRS).

FIG. 5B depicts the scenario with a p-type semiconductor for the ox-channel 104b′ where the polarization P of the ferroelectric material 104a′ points away from the ox-channel 104b′. Sec arrows 504B. This results in accumulation of the main charge carriers in the ox-channel 104b′ (holes h⁺) as indicated by ‘+’ symbols 506, and therefore multi-logic ‘1’ resistance levels (LRS).

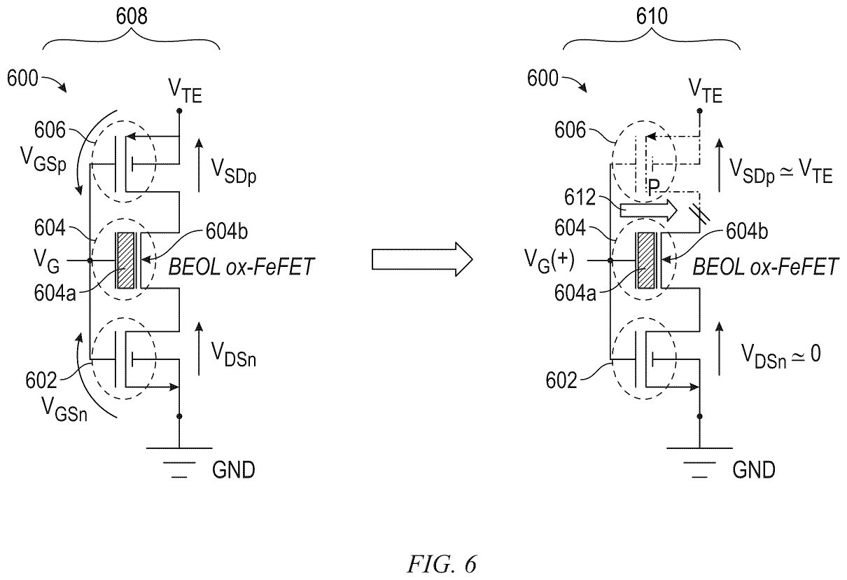

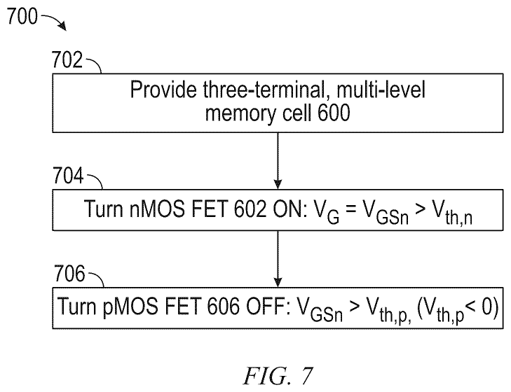

Techniques for multi-level write and read operations of the present memory cell are now described. For instance, FIG. 6 and FIG. 7 illustrate the writing of a multi-level state where the net polarization P of the ferroelectric material points toward the ox-channel. As above, the memory cell 600 in question includes a cascade of three elements, i.e., an nMOS FET 602 located in the FEOL, an ox-FeFET 604 located in the BEOL that is connected to the nMOS FET 602, and a pMOS FET 606 located in the FEOL that is connected to the ox-FeFET 604. Beginning with the (pre-programming) state 608, sweeping the V_{TE} and the V_{G} accordingly allows for multi-level programming of the memory cell 600, to where a net polarization P of a ferroelectric material 604a of the ox-FeFET 604 points either toward or away from an ox-channel 604b of the ox-FeFET 604. The relevant parameters for these operations, i.e., gate-source voltage of the nMOS FET 602 (V_{GSn}), drain-source voltage of the nMOS FET 602 (V_{DSn}), gate-source voltage of the pMOS FET 606 (V_{GSp}), and source-drain voltage of the pMOS FET 606 (V_{SDp}), are shown.

Referring briefly to methodology 700 of FIG. 7, in step 702 the above-described memory cell 600 is provided. The V_{TE} (applied to the TE terminal) and the V_{G} (applied to the common gate (G)) are then controlled to perform multi-level programming of the memory cell 600. For instance, the present example involves the writing of a multi-level state where the net polarization P of the ferroelectric material 604a of the ox-FeFET 604 points toward the ox-channel 604b. Doing so involves turning the nMOS FET 602 ON in step 704. The operative condition for turning the nMOS FET 602 ON is:

$${V}_{G} = {V}_{GSn} > {V}_{th , n} , \qquad ( 1 )$$

where V_{th,n} is the threshold voltage of the nMOS FET 602. Accordingly, the V_{G} is above the threshold of the nMOS FET 602, i.e.,
and the nMOS FET 602 is ON.

$${V}_{G} > {V}_{th , n} , \qquad ( 2 )$$

In step 706, the pMOS FET 606 is turned OFF. The operative condition for turning the pMOS FET 606 OFF is:

$${V}_{GSp} > {V}_{th , p} , \qquad ( 3 )$$

where V_{th,p} is the threshold voltage of the pMOS FET 606, and where V_{th,p}<0. The operative condition for turning the pMOS FET 606 OFF may be derived as follows:

$${V}_{SGp} = {V}_{TE} - {V}_{G} \qquad ( 4 )$$

$${V}_{GSp} = {V}_{G} - {V}_{TE} > {V}_{th , p}$$

$${V}_{G} > {V}_{TE} + {V}_{th , p} , ( {V}_{th , p} < 0 )$$

$${V}_{G} > {V}_{TE} - \vert {V}_{th , p} \vert ,$$

where V_{SGp} is the source-gate voltage of the pMOS FET 606. Given Equations 2 and 4, above, the following constraints on V_{G} and V_{TE} need to be met in order to write a multi-level state where the net polarization P of the ferroelectric material 604a of the ox-FeFET 604 points toward the ox-channel 604b:

$${V}_{G} > max ( {V}_{th , n} , {V}_{TE} - \vert {V}_{th , p} \vert ) \qquad ( 5 )$$

$${V}_{TE} > {V}_{th , n} . \qquad ( 6 )$$

Namely, these constraints require that V_{G} applied to the common gate (G) terminal is greater than the maximum of the two values, V_{th,n} and V_{TE}−|V_{th,p}|, and that V_{TE} applied to the TE terminal is greater than the V_{th,n} of the nMOS FET 602.

Referring back to FIG. 6, implementation of these operative conditions is illustrated schematically in (programmed) state 610. Namely, the same standard line graphic used throughout is employed for the nMOS FET 602 to indicate that the nMOS FET 602 is now turned ON and is above V_{th,n} (i.e., the V_{G} is at least equal to the threshold of the V_{th,n} and the V_{th,n} is ON). On the other hand, the pMOS FET 606 is now turned OFF, and a different graphic is used to depict the pMOS FET 606 to indicate that the pMOS FET 606 is now turned OFF.

If these operating conditions are satisfied such that the nMOS FET 602 is ON and the pMOS FET 606 is OFF as per steps 704 and 706 of methodology 700, respectively, then no current is flowing through the cascade of elements (i.e., nMOS FET 602, ox-FeFET 604 and pMOS FET 606). However, since the nMOS FET 602 is turned ON, the V_{DSn} of nMOS FET 602 is practically zero (V_{DSn}≃0). As such, there is essentially a ground on one of the terminals of the ox-FeFET 604, and applying a positive V_{G} (+) that is greater than max (V_{th,n}, V_{TE}−|V_{th,p}|) (as per Equation 5 above) will program the state where the net polarization P of the ferroelectric material 604a of the ox-FeFET 604 points toward the ox-channel 604b of the ox-FeFET 604. See arrow 612.

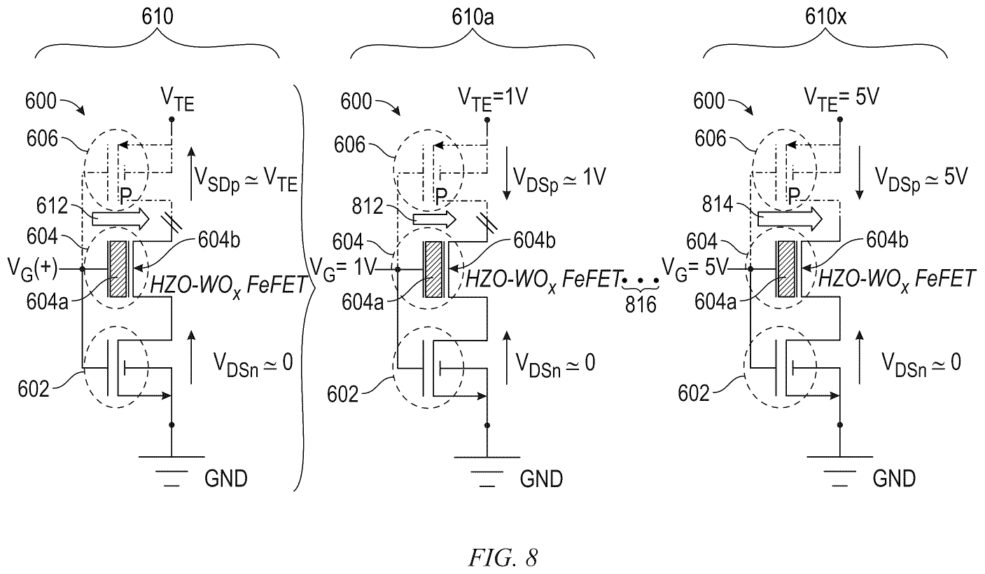

An illustrative, non-limiting example of this programming scheme is shown in FIG. 8. Notably, FIG. 8 highlights how the higher the V_{TE} and V_{G} voltage used, the higher the polarization P that will be stored in the ferroelectric material 604a of the ox-FeFET 604.

For example, to achieve the multi-level programmed state 610 where the net polarization P of the ferroelectric material 604a of the ox-FeFET 604 points toward the ox-channel 604b of the ox-FeFET 604, in one instance a V_{TE}=1V is applied on the TE terminal, and a V_{G}=1V is applied on the gate G terminal. As highlighted above, under the constraints where V_{G} is greater than the maximum of V_{th,n} and V_{TE}−|V_{th,p}|, and V_{TE} is greater than the V_{th,n} of the nMOS FET 602, the channel of the ox-FeFET 604 is essentially at ground. The net polarization P of the ferroelectric material 604a of the ox-FeFET 604 will accordingly be forced to point towards the ox-channel 604b of the ox-FeFET 604 at a level indicated by the (relatively smaller) arrow 812 in state 610a.

By comparison, under the same constraints, applying a higher voltage V_{TE}=5V on the TE terminal, and a V_{G}=5V on the gate G terminal stores another level. Sec, e.g., arrow 814 in state 610x. Arrow 814 is shown to be relatively larger than arrow 812 in order to indicate that the net polarization P (pointing towards the ox-channel 604b) stored in the ferroelectric material 604a of the ox-FeFET 604 in state 610x is larger than the net polarization P stored in the ferroelectric material 604a of the ox-FeFET 604 in state 610a, based on the latter being programmed using a higher voltage V_{TE} and V_{G}. Dots 816 are used to indicate that there are multiple intermediate states which can be programmed in between state 610a and state 610x.

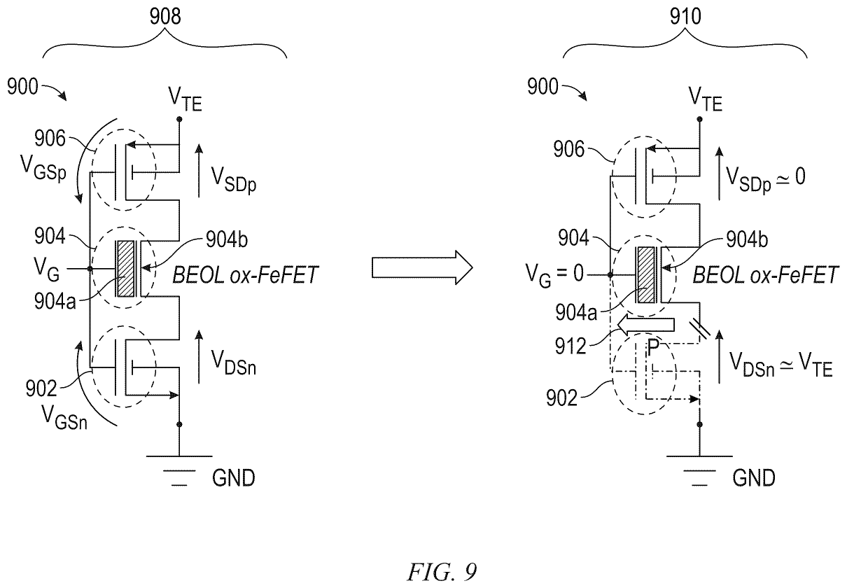

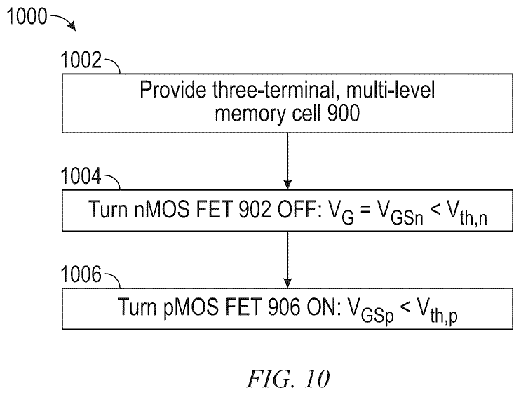

In contrast to the preceding example, FIG. 9 and FIG. 10 illustrate the writing of a multi-level state where the net polarization P of the ferroelectric material points outward/away from the ox-channel. As above, the memory cell 900 in question includes a cascade of three elements, i.e., an nMOS FET 902 located in the FEOL, an ox-FeFET 904 located in the BEOL that is connected to the nMOS FET 902, and a pMOS FET 906 located in the FEOL that is connected to the ox-FeFET 904. Beginning with the (pre-programming) state 908, sweeping the V_{TE} and the V_{G} accordingly allows for multi-level programming of the memory cell 900, to where a net polarization P of a ferroelectric material 904a of the ox-FeFET 904 points either toward or away from an ox-channel 904b of the ox-FeFET 904. The relevant parameters for these operations, i.e., V_{GSn} of the nMOS FET 902, V_{DSn} of the nMOS FET 902, V_{GSp} of the pMOS FET 906, and V_{SDp} of the pMOS FET 906, are shown.

Referring briefly to methodology 1000 of FIG. 10, in step 1002 the above-described memory cell 900 is provided. The V_{TE} (applied to the TE terminal) and the V_{G} (applied to the common gate (G)) are then controlled to perform multi-level programming of the memory cell 900. For instance, the present example involves the writing of a multi-level state where the net polarization P of the ferroelectric material 904a of the ox-FeFET 904 points away from the ox-channel 904b. Doing so involves turning the nMOS FET 902 OFF in step 1004. The operative condition for turning the nMOS FET 902 OFF is:

$${V}_{G} = {V}_{GSn} < {V}_{th , n} . \qquad ( 7 )$$

Accordingly, the V_{G} is below the threshold of the nMOS FET 902, i.e.,

$${V}_{G} < {V}_{th , n} , \qquad ( 8 )$$

and the nMOS FET 902 is OFF.

In step 1006, the pMOS FET 906 is turned ON. The operative condition for turning the pMOS FET 906 ON is:

$${V}_{GSp} < {V}_{th , p} , \qquad ( 9 )$$

where V_{th,p}<0. The operative condition for turning the pMOS FET 906 ON may be derived as follows:

$${V}_{SGp} = {V}_{TE} - {V}_{G} \qquad ( 10 )$$

$${V}_{GSp} = {V}_{G} - {V}_{TE} < {V}_{th , p}$$

$${V}_{G} < {V}_{TE} + {V}_{th , p} , ( {V}_{th , p} < 0 )$$

$${V}_{G} < {V}_{TE} - \vert {V}_{th , p} \vert .$$

Given Equations 8 and 10, above, the following constraints on V_{G} and V_{TE} need to be met in order to write a multi-level state where the net polarization P of the ferroelectric material 904a of the ox-FeFET 904 points away from the ox-channel 904b:

$${V}_{G} < min ( {V}_{th , n} , {V}_{TE} - \vert {V}_{th , p} \vert ) \qquad ( 11 )$$

$${V}_{TE} > \vert {V}_{th , p} \vert . \qquad ( 12 )$$

Namely, these constraints require that V_{G} applied to the common gate (G) terminal is less than the minimum of the two values, V_{th,n} and V_{TE}−|V_{th,p}|, and that V_{TE} applied to the TE terminal is greater than the |V_{th,p}| of the pMOS FET 906.

Referring back to FIG. 9, implementation of these operative conditions is illustrated schematically in (programmed) state 910. Namely, the same standard line graphic used throughout is employed for the pMOS FET 906 to indicate that the pMOS FET 906 is now turned ON. On the other hand, the nMOS FET 902 is now turned OFF, and a different graphic is used to depict the nMOS FET 902 to indicate that the nMOS FET 902 is now turned OFF.

If these operating conditions are satisfied such that the nMOS FET 902 is OFF and the pMOS FET 906 is ON as per steps 1004 and 1006 of methodology 1000, respectively, then a net current in the cascade of elements (i.e., nMOS FET 902, ox-FeFET 904 and pMOS FET 906) is zero (0). In this case, however, applying zero V_{G} on the common gate (G) terminal (V_{G}=0) and a positive V_{TE} on the TE terminal forces the ox-channel 904b of the ox-FeFET 904 to be at the V_{TE} (based on the positive V_{TE} on the ox-channel 904b and V_{G}=0). Doing so will force the net polarization P of the ferroelectric material 904a of the ox-FeFET 904 to point away from the ox-channel 904b due to the high V_{TE} and low/zero V_{G}.

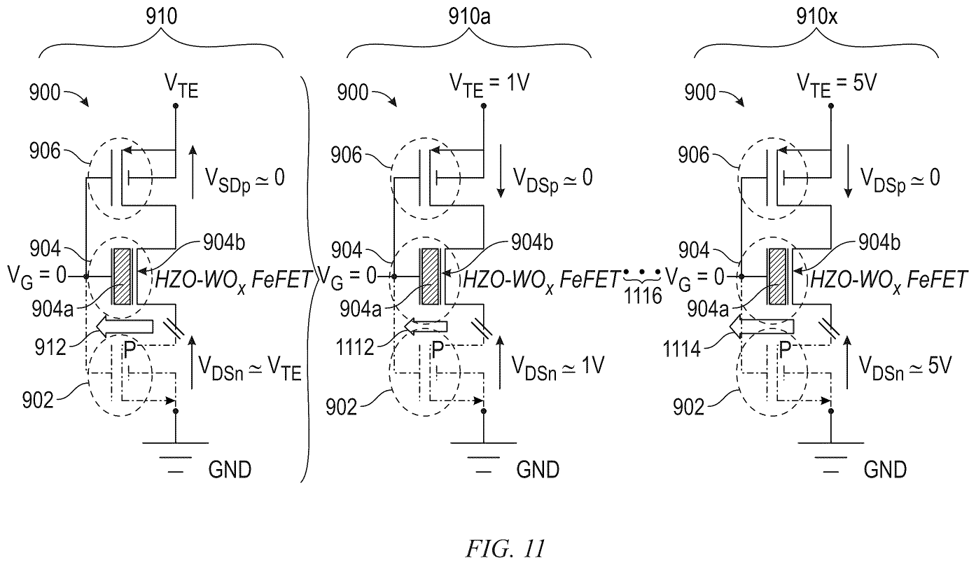

An illustrative, non-limiting example of this programming scheme is shown in FIG. 11. Notably, FIG. 11 highlights how the higher the V_{TE} voltage used, the higher the polarization P that will be stored in the ferroelectric material 904a of the ox-FeFET 904. For example, to achieve the multi-level programmed state 910 where the net polarization P of the ferroelectric material 904a of the ox-FeFET 904 points away from the ox-channel 904b of the ox-FeFET 904, in one instance a V_{TE}=1V is applied on the TE terminal, and a V_{G}=0 is applied on the gate (G) terminal. As highlighted above, under the constraints where V_{G} is less than the minimum of the two values, V_{th,n} and V_{TE}−|V_{th,p}|, and V_{TE} is greater than the |V_{th,p}| of the pMOS FET 906, the net polarization P of the ferroelectric material 904a of the ox-FeFET 904 will be forced to point away from the ox-channel 904b of the ox-FeFET 904 at a level indicated by the (relatively smaller) arrow 1112 in state 910a.

By comparison, under the same constraints, applying a higher voltage V_{TE}=5V on the TE terminal, and a V_{G}=0 on the gate (G) terminal stores another level. See, e.g., arrow 1114 in state 910x. Arrow 1114 is shown to be relatively larger than arrow 1112 in order to indicate that the net polarization P (pointing away from the ox-channel 904b) stored in the ferroelectric material 904a of the ox-FeFET 904 in state 910x is larger than the net polarization P stored in the ferroelectric material 904a of the ox-FeFET 904 in state 910a, based on the latter being programmed using a higher voltage V_{TE}. As above, dots 1116 are used to indicate that there are multiple intermediate states which can be programmed in between state 910a and state 910x.

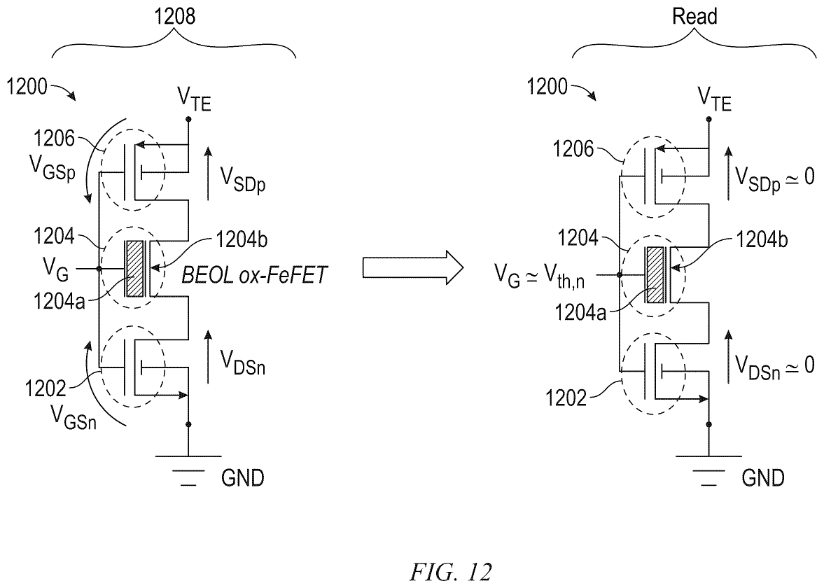

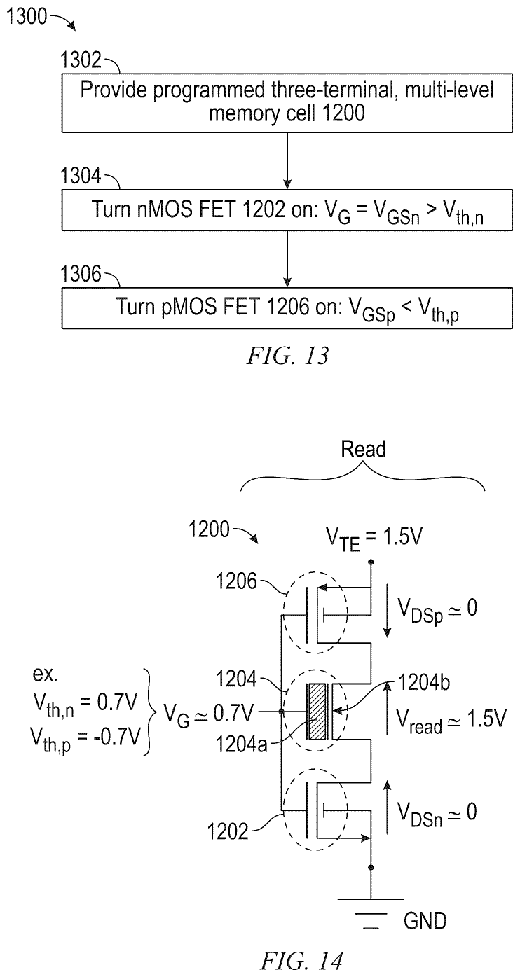

Once the present memory cell is written in one direction (e.g., with the net polarization P of the ferroelectric material of the ox-FeFET pointing either towards or away from the ox-channel as described above), certain operative conditions can then be employed to read the information stored in the memory cell. There are, however, certain constraints on the read voltage (V_{read}) in order to perform a non-destructive read operation (i.e., where the information stored in the memory cell is retained). Sec, e.g., FIG. 12 and FIG. 13.

As above, the memory cell 1200 in question includes a cascade of three elements, i.e., an nMOS FET 1202 located in the FEOL, an ox-FeFET 1204 located in the BEOL that is connected to the nMOS FET 1202, and a pMOS FET 1206 located in the FEOL that is connected to the ox-FeFET 1204. Beginning with the (programmed) state 1208 where the net polarization P of the ferroelectric material 1204a of the ox-FeFET 1204 points either towards or away from the ox-channel 1204b of the ox-FeFET 1204 in the same manner as described above, a low energy and non-destructive Read operation can be performed to extract the information stored in the memory cell 1200. The relevant parameters for this operation, i.e., V_{GSn} of the nMOS FET 1202, V_{DSn} of the nMOS FET 1202, V_{GSp} of the pMOS FET 1206, and V_{SDp} of the pMOS FET 1206, are shown.

Referring briefly to methodology 1300 of FIG. 13, in step 1302 the above-described memory cell 1200 is provided and which has been programmed to a state where the net polarization P of the ferroelectric material 1204a of the ox-FeFET 1204 points either towards or away from the ox-channel 1204b of the ox-FeFET 1204 as described in conjunction with the descriptions of FIG. 7 and FIG. 10, respectively, above. The V_{TE} (applied to the TE terminal) and the V_{G} (applied to the common gate (G)) are then controlled to read the programmed information stored in the memory cell 1200. Doing so involves turning the nMOS FET 1202 ON in step 1304. As per Equation 1 above, the operative condition for turning the nMOS FET 1202 ON is V_{G}=V_{GSn}>V_{th,n}. Accordingly, the V_{G} is above the threshold of the nMOS FET 1202, i.e., V_{G}>V_{th,n}, and the nMOS FET 1202 is ON.

In step 1306, the pMOS FET 1206 is also turned ON. As per Equation 9 above, the operative condition for turning the pMOS FET 1206 ON is V_{GSp}<V_{th,p}, where V_{th,p}<0. The process as above may be employed for deriving the operative condition, i.e., V_{G}<V_{TE}−|V_{th,p}| (see Equation 10) for turning the pMOS FET 1206 ON. Given Equations 2 and 10, above, the following constraints on V_{G} and V_{TE} need to be met in order to perform a non-destructive read of the (programmed) memory cell 1200:

$${V}_{th , n} < {V}_{G} < {V}_{TE} - \vert {V}_{th , p} \vert \qquad ( 13 )$$

$${V}_{TE} > {V}_{th , n} + \vert {V}_{th , p} \vert \qquad ( 14 )$$

$${V}_{read} ≃ {V}_{TE} > {V}_{th , n} + \vert {V}_{th , p} \vert . \qquad ( 15 )$$

Referring back to FIG. 12 and the operation labeled “Read,” applying a V_{read}≃V_{TE}>V_{th,n}+|V_{th,p}| to the TE terminal and a V_{G}≃V_{th,n} to the common gate (G) terminal will satisfy these conditions, turning both the nMOS FET 1202 ON and the pMOS FET 1206 ON as per steps 1304 and 1306 of methodology 1300, respectively, and thereby enabling a non-destructive read of the state of the programmed memory cell 1200.

An illustrative, non-limiting example of this read scheme is shown in FIG. 14. In this instance, V_{th,n}=0.7V and V_{th,p}=−0.7V are given as exemplary threshold values for the nMOS FET 1202 and pMOS FET 1206, respectively. Thus, for the constraints V_{read}≃V_{TE}>V_{th,n}+|V_{th,p}| and V_{G}≃V_{th,n}, a V_{G} of about 0.7V is applied to the common gate (G) terminal and a minimum V_{read} of 1.5V is applied to the TE terminal. Doing so will enable a non-destructive read of the information stored in the memory cell 1200. Notably, since the ox-FeFET 1204 has an ohmic ox-channel 1204b (exhibiting linear conduction), the resistance reading does not depend on the read voltage being used. Thus, for example, whether the V_{read} is 1.5V or 2.0V one would get the same resistance (i.e., the same information would be read from the memory cell 1200).

So far, the description has centered on the configuration and operation of individual 1T1Fe1T multi-level memory cells. However, embodiments are considered herein where a memory device includes a multitude of the above-described memory cells arranged in a matrix to further multiply the capabilities of having many memory cells employed together, each of which has multi-level storage capabilities that can be programmed and accessed in the same manner described above. Namely, the 1T1Fe1T memory cell design described up to this point is now being put in a matrix to further multiply the capabilities of having many memory cells together with a multi-level state for each individual memory cell. The following will describe in detail how to connect this matrix and still be able to write/read all of these levels.

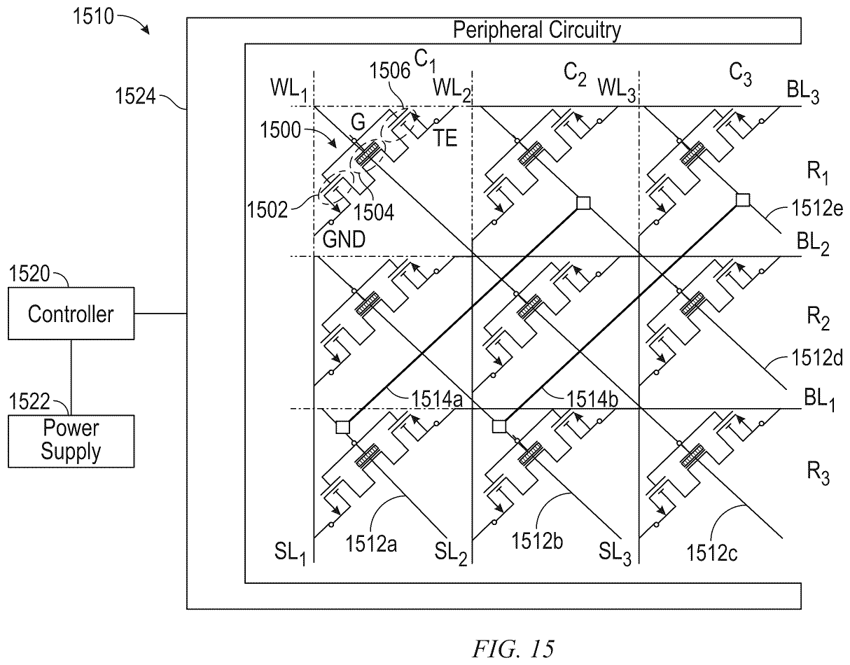

For instance, FIG. 15 depicts a multi-cell memory device 1510 having a high-density crossbar array containing a plurality of the present memory cells interconnected by a grid of horizontal bit lines (i.e., BL₁, BL₂, BL₃, etc.), vertical source lines (i.e., SL₁, SL₂, SL₃, etc.), and diagonal word lines (i.e., WL₁, WL₂, WL₃, etc.). Specifically, as shown in FIG. 15, in the same manner as above each memory cell 1500 in multi-cell memory device 1510 includes a cascade of three elements, i.e., an nMOS FET 1502 located in the FEOL, an ox-FeFET 1504 located in the BEOL that is connected to the nMOS FET 1502, and a pMOS FET 1506 located in the FEOL that is connected to the ox-FeFET 1504, and three terminals, i.e., a TE terminal, a gate (G) terminal, and a GND terminal.

The grid pattern of the bit lines (i.e., BL₁, BL₂, BL₃, etc.) and source lines (i.e., SL₁, SL₂, SL₃, etc.) defines a set of rows (i.e., R₁, R₂, R₃, etc.) and a set of columns (i.e., C₁, C₂, C₃, etc.). As shown in FIG. 15, the bit lines connect the sources (Sp) of the pMOS FET 1506 of all of the memory cells 1500 along a given row via the TE terminal. For instance, BL₁ connects the TE terminal of the memory cell 1500 at C₁/R₃ to the TE terminal of the memory cell 1500 at C₂/R₃, and to the TE terminal of the memory cell 1500 at C₃/R₃, etc. Likewise, BL₂ connects the TE terminal of the memory cell 1500 at C₁/R₂ to the TE terminal of the memory cell 1500 at C₂/R₂, and to the TE terminal of the memory cell 1500 at C₃/R₂, etc. And so on.

The source lines, which are oriented orthogonal to the bit lines, connect the sources (Sn) of the nMOS FET 1502 of all of the memory cells 1500 along a given column via the GND terminal. For instance, SL₁ connects the GND terminal of the memory cell 1500 at C₁/R₁ to the GND terminal of the memory cell 1500 at C₁/R₂, and to the GND terminal of the memory cell 1500 at C₁/R₃, etc. Likewise, SL₂ connects the GND terminal of the memory cell 1500 at C₂/R₁ to the GND terminal of the memory cell 1500 at C₂/R₂, and to the GND terminal of the memory cell 1500 at C₂/R₂, etc. And so on.

The word lines are oriented diagonal to the bit lines and source lines, and connect the common gate (G) terminals of the memory cells 1500 in a pattern crisscrossing adjacent bit lines and source lines. Notably, according to an exemplary embodiment, the word lines are located in at least two different metal levels of the multi-cell memory device 1510 in order to avoid the unintended shorting of a word line in one level to an unassociated word line in another level. Namely, as shown in FIG. 15, in no particular order, the word lines include first metal lines 1512a,b,c,d,e,etc. located in a first metal level and oriented orthogonal to second metal lines 1514a,b,etc. located in a second metal level. The first metal level may be located above the second metal level, or vice versa. As would be understood by one of ordinary skill in the art, a metal level is a layer(s) of an integrated circuit architecture that contains conductive structures like vias and metal lines interspersed with dielectric material which can be employed to connect a device to one or more other devices, to external connections, and the like, with the metal lines making lateral connections and the vias making vertical connections amongst different metallization levels.

For instance, WL₁ connects the gate (G) terminal of the memory cell 1500 at C₁/R₁ to the gate (G) terminal of the memory cell 1500 at C₂/R₂, and to the gate (G) terminal of the memory cell 1500 at C₃/R₃, etc. via first word line 1512c. WL₂ connects the gate (G) terminal of the memory cell 1500 at C₂/R₁ to the gate (G) terminal of the memory cell 1500 at C₃/R₂, etc. via first word line 1512d and, via the second word line 1514a, to the gate (G) terminal of the memory cell 1500 at C₁/R₃. Similarly, via first word line 1512e, second word line 1514b, and first word line 1512b, WL₃ connects the gate (G) terminal of the memory cell 1500 at C₃/R₁ to the gate (G) terminal of the memory cell 1500 at C₂/R₃, etc. And so on.

By configuring the bit lines (i.e., BL₁, BL₂, BL₃, etc.), source lines (i.e., SL₁, SL₂, SL₃, etc.), and word lines (i.e., WL₁, WL₂, WL₃, etc.) in this manner, any single memory cell 1500 can be individually accessed without perturbation of any of the other memory cells 1500 in the crossbar array. More specifically, only the selected memory cell 1500 sees all three of the bit line, source line, and word line signals, while all of the other memory cells 1500 in the crossbar array see at most one other signal. This means that there is no current flowing for all those other memory cells 1500 in the crossbar array, and thus they are not disturbed. Take, for instance, the case where BL₃, SL₁, and WL₁ signals are applied to the crossbar array. Only the memory cell 1500 at C₁/R₁ will be selected. All of the other memory cells 1500 along the BL₃ will see at most just a bit line signal, all of the other memory cells 1500 along the SL₁ will see at most just a source line signal, and so on.

As shown in FIG. 15, according to an exemplary embodiment, there is peripheral circuitry 1524 coupled to the bit lines, source lines, and word lines, a power supply 1522, and a controller 1520 coupled to the power supply 1522 and the peripheral circuitry 1524. The power supply 1522 can be controlled by the controller 1520 to supply appropriate voltages, and can be part of the controller 1520 or a separate unit. These elements are cooperatively configured for input/output and so on. Given the teachings herein, the skilled artisan will be able to provide any additional desired/required peripheral circuitry, voltage/power supply, elements to interface with peripheral circuitry, and the controller by adapting known techniques. To implement any of the digital circuitry described herein, computer-aided semiconductor integrated circuit (IC) logic design, simulation, test, layout, and/or manufacture can be employed. The computerized design process can represent functional and/or structural design features in a design structure generated using electronic computer-aided design (ECAD). A suitable hardware-description language (HDL) can be employed. The skilled artisan can synthesize digital logic circuits to carry out desired control and other functionality, using known computer-aided design techniques. The controller 1520 carries out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry using a known design flow process used for example, in semiconductor IC logic design, simulation, test, layout, and manufacture. Such a known design flow for synthesizing digital circuitry includes processes, machines and/or mechanisms for processing design structures or devices to generate logically or otherwise functionally equivalent representations of design structures and/or devices. The design structures processed can be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array). Design structures can be generated using ECAD. Use can be made of HDL design entities or other data structures conforming to and/or compatible with lower-level HDL design languages such as Verilog and VHDL, and/or higher level design languages such as C or C++.

It is notable that FIG. 15 depicts a high-level schematic of the peripheral circuitry 1524, power supply 1522, and controller 1520. However, given the teachings herein, the skilled artisan can make appropriate connections to the bit lines, source lines, and word lines and can add any additional elements as may be needed depending on the particular application at hand. Further, while the peripheral circuitry 1524, power supply 1522, and controller 1520, etc. are not shown in the figures that follow, this is done merely for case and clarity of depiction, and it would be understood by one skilled in the art that said peripheral circuitry 1524, power supply 1522, and controller 1520, etc. would be implemented in the same manner as shown in FIG. 15.

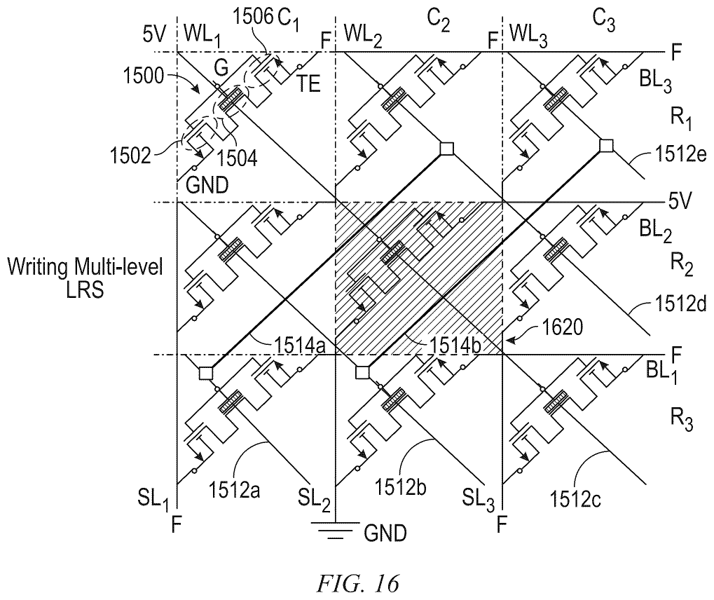

The write and read operations for multi-cell memory device 1510 follow the same basic procedures detailed above. See, for example, FIGS. 16-18 which illustrate the independent write and read operations of any one memory cell 1500 in the crossbar array. Specifically, FIG. 16 is an example showing the independent writing of a multi-level LRS (i.e., the LRS and all of the intermediate states) in a select memory cell 1500 in the crossbar array (i.e., the memory cell 1500 within dashed box 1620). To do so, in this example, 5V is applied to BL₂, SL₂ is connected to GND, and 5V is applied to WL₁, while all other bit lines, source lines, and word lines are floating (F). This will result in the addressing and writing the multi-level LRS of the memory cell 1500 in box 1620. All other memory cells 1500 in the crossbar array will have, at most, one signal during this writing operation.

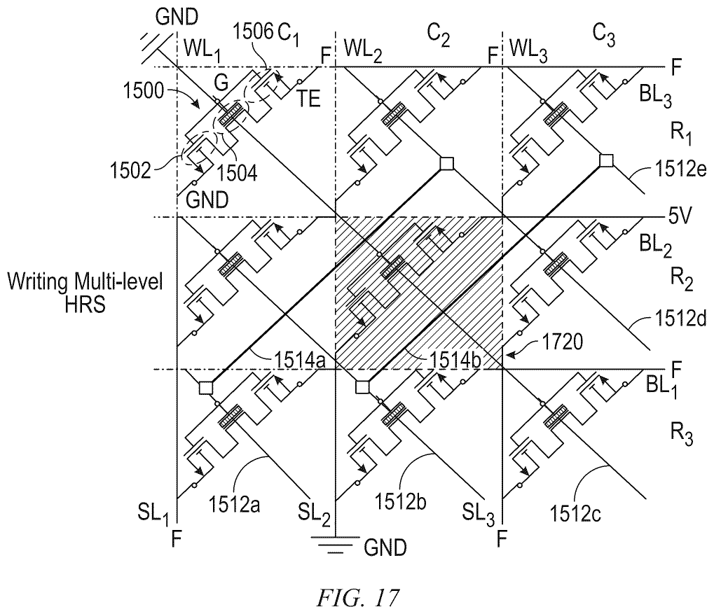

A similar approach can be employed for independently writing the multi-level HRS (i.e., the HRS and all of the intermediate states) in a select memory cell 1500 in the crossbar array (i.e., the memory cell 1500 within dashed box 1720). See FIG. 17. To do so, in this example, 5V is applied to BL₂, SL₂ is connected to GND, and WL₁ is connected to GND, while all other bit lines, source lines, and word lines are floating (F). This will result in the addressing and writing the multi-level HRS of the memory cell 1500 in box 1720. As above, all other memory cells 1500 in the crossbar array will have, at most, one signal during this writing operation.

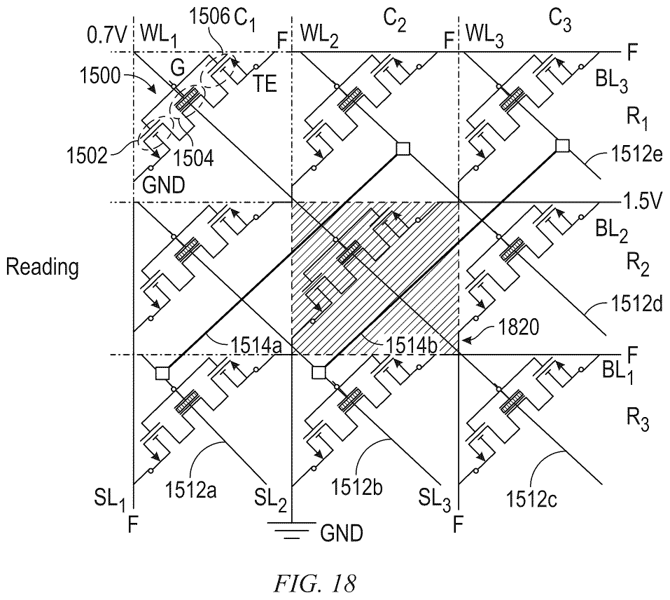

FIG. 18 is an example showing the independent reading the multi-level state of a select memory cell 1500 in the crossbar array (i.e., the memory cell 1500 within dashed box 1820). See FIG. 18. To do so, in this example, 1.5V is applied to BL₂, SL₂ is connected to GND, and 0.7V is applied to WL₁, while all other bit lines, source lines, and word lines are floating (F). This will result in the addressing and reading of the multi-level state of the memory cell 1500 in box 1820. All other memory cells 1500 in the crossbar array will have, at most, one signal during this reading operation.

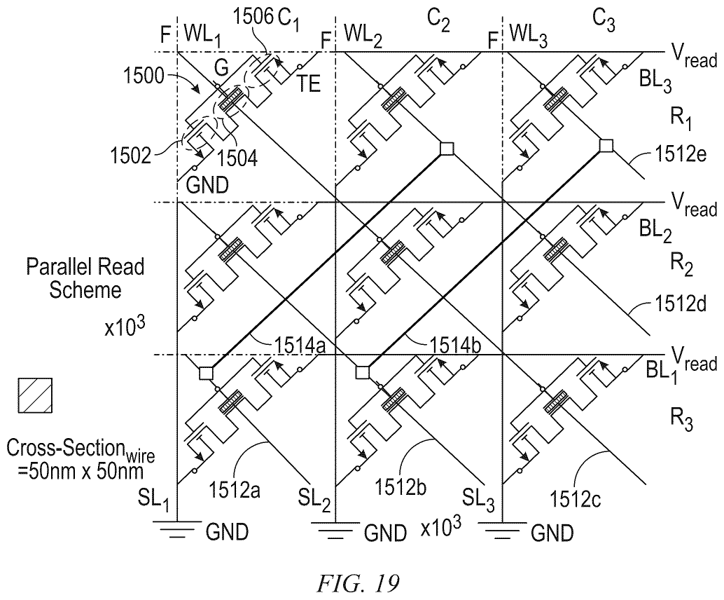

In the preceding example, the multi-level state of a select memory cell 1500 in the crossbar array is independently read. However, embodiments are also contemplated herein where a parallel read scheme is employed in which all of the memory cells 1500 in the crossbar array can be read in parallel, in one shot. See, for example, FIG. 19. As shown in this particular example, suppose that the crossbar array has 1000×1000 memory cells 1500. If the same V_{read} is applied to all of the bit lines (i.e., BL₁, BL₂, BL₃, etc.), all of the source lines (i.e., SL₁, SL₂, SL₃, etc.) are connected to GND, and the word lines (i.e., WL₁, WL₂, WL₃, etc.) are floating (F), then all of the memory cells 1500 can be read in parallel.

In that regard, factors such as parasitic resistance drop (IR drop) along the metal lines of the crossbar array should also be considered. Namely, in the present example, when applying V_{read} to a given one of the bit lines, the goal is to provide the same signal to the memory cell 1500 at the beginning of that bit line as to the last memory cell 1500 at the end of that bit line. However, there is some (unwanted) IR drop along the bit line that needs to be factored into the V_{read} value. In that case, the V_{read} has to be larger than the threshold of the nMOS FET 1502 (V_{th,n}) and the threshold of the pMOS FET 1506 (V_{th,p}), as described above, plus the IR drop, i.e.,

$${V}_{read} ≃ {V}_{TE} > {V}_{th , n} + \vert {V}_{th , p} \vert + {I - R}_{wire} drop \qquad ( 16 )$$

The V_{read} can then be adjusted accordingly to account for the architectural arrangement.

For instance, by way of non-limiting example only, assume that the (metal) bit lines, source lines and word lines each has a cross-sectional dimension (Cross-section_{wire}) of 50 nm×50 nm. See FIG. 19. The IR drop can then be easily computed considering the resistance (R) of a copper (Cu) metal line as follows:

$${G}_{wire - Cu} = {σ}_{Cu} \frac{\text{Cross-sectionwire}}{{L}_{wire}} = 500 μ S \qquad ( 17 )$$

$${G}_{eq}^{FeFET} = {\sum }_{i = 1}^{1000} {G}_{i}^{FeFET} = 100 μ S , \qquad ( 18 )$$

where G is the conductance of each Cu line measured in microsiemens (μS), and G^{FeFET} is the conductance of the present ox-FeFET 1504. As above, it is assumed that the crossbar array has 1000×1000 memory cells 1500 which are summed up in Equation 18. For this computation, a value of Gᵢ^{FeFET}=0.1 μS is employed. Thus, from the difference between Equations 17 and 18, it can be seen that, even with such a large crossbar array, there is only an IR drop of up to 20% of the V_{read}, i.e., I-R_{wire} drop=20% V_{read}.

Notably, as highlighted above, the present 1T1Fe1T memory cell designs offer distinct advantages over conventional memory technologies. For instance, as compared to standard SRAM designs, the present memory designs permit greater than three times the device density due to smaller memory cell area, and are non-volatile. Further, as provided above, the present crossbar architectures enable a parallel read scheme. As compared to Flash memory, the writing energy is significantly lower for the present devices, i.e., less than 5V for the present 1T1Fe1T memory cells as compared to about 10V for flash memory, and the endurance for the present 1T1Fe1T memory cells is 1×10⁴ larger than that of Flash memory. As would be understood by one of ordinary skill in the art, endurance refers generally to the number of times a memory cell can be written before it becomes unreliable. Also, as provided above, the present crossbar architectures enable a parallel read scheme.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A memory cell, comprising:
a cascade of elements all sharing a common gate terminal and, via the common gate terminal, a common gate voltage V_{G}, wherein the cascade of elements comprises:
an n-doped metal oxide semiconductor (nMOS) field-effect transistor (FET);
an oxide-ferroelectric FET (ox-FeFET) located in a Back-End-of-Line (BEOL) that is connected to the nMOS FET; and
a p-doped metal oxide semiconductor (pMOS) FET that is connected to the ox-FeFET.

2. The memory cell of claim 1, wherein the nMOS FET and the pMOS FET are both located in a Front-End-of-Line (FEOL).

3. The memory cell of claim 1, further comprising:
a top electrode terminal; and
a ground terminal, wherein the nMOS FET is connected to the ox-FeFET and to the ground terminal, and wherein the pMOS FET is connected to the ox-FeFET and to the top electrode terminal.

4. The memory cell of claim 1, wherein the ox-FeFET comprises:
an oxide channel (ox-channel);
a ferroelectric material disposed on the ox-channel; and
a metal gate disposed on the ferroelectric material, wherein the metal gate is connected to the common gate terminal.

5. The memory cell of claim 4, wherein the ferroelectric material comprises a hafnium oxide (HfO₂)-based material selected from the group consisting of: pure HfO₂, hafnium zirconate (Hf_{-0.5}Zr_{-0.5}O₂), HfO₂ doped with at least one of nitrogen (N), carbon (C), silicon (Si), aluminum (Al), lanthanum (La), gadolinium (Gd), yttrium (Y), scandium (Sc), strontium (Sr), and combinations thereof.

6. The memory cell of claim 4, wherein the ox-channel comprises an n-type oxide semiconductor material selected from the group consisting of: tungsten oxide (WOₓ), tantalum oxide (TaOₓ), titanium oxide (TiOₓ), indium gallium zinc oxide (IGZO), and combinations thereof.

7. The memory cell of claim 4, wherein the ox-channel comprises a p-type oxide semiconductor material selected from the group consisting of: copper oxide (Cu₂O), nickel oxide (NiO), tin oxide (SnO), and combinations thereof.

8. The memory cell of claim 1, wherein the ox-FeFET comprises:
a metal gate connected to the common gate terminal;
a ferroelectric material disposed on the metal gate; and
an oxide channel disposed on the ferroelectric material.

9. A multi-cell memory device, comprising:
bit lines;
source lines oriented orthogonal to the bit lines, wherein the bit lines and the source lines define a set of rows and columns of the multi-cell memory device;
word lines oriented diagonal to the bit lines and the source lines; and
a plurality of memory cells interconnected by the bit lines, source lines and word lines, wherein the plurality of memory cells each comprises a cascade of elements all sharing a common gate terminal and, via the common gate terminal, a common gate voltage V_{G}, and wherein the cascade of elements comprises: an n-doped metal oxide semiconductor (nMOS) field-effect transistor (FET), an oxide-ferroelectric FET (ox-FeFET) located in a Back-End-of-Line (BEOL) that is connected to the nMOS FET and a p-doped metal oxide semiconductor (pMOS) FET that is connected to the ox-FeFET.

10. The memory device of claim 9, wherein the plurality of memory cells each further comprises:
a top electrode terminal; and
a ground terminal, wherein the nMOS FET is connected to the ox-FeFET and to the ground terminal, and wherein the pMOS FET is connected to the ox-FeFET and to the top electrode terminal.

11. The memory device of claim 10, wherein the bit lines connect all of the plurality of memory cells along a given one of the rows via the top electrode terminal, and wherein the source lines connect all of the plurality of memory cells along a given one of the columns via the ground terminal.

12. The memory device of claim 11, wherein the word lines connect the plurality of memory cells in a pattern crisscrossing adjacent ones of the bit lines and the source lines via the common gate terminal.

13. The memory device of claim 11, wherein the word lines are located in at least two different metal levels of the multi-cell memory device.

14. A method, comprising:
providing a memory cell having a cascade of elements all sharing a common gate terminal, wherein the cascade of elements comprises: an nMOS FET, an ox-FeFET located in a BEOL, and a pMOS FET, and wherein the nMOS FET is connected to the ox-FeFET and to a ground terminal, and wherein the pMOS FET is connected to the ox-FeFET and to a top electrode terminal; and
controlling a top electrode voltage (V_{TE}) applied to the top electrode terminal and a gate voltage (V_{G}) applied to the common gate terminal to perform multi-level programming of the memory cell.

15. The method of claim 14, further comprising:
turning the nMOS FET ON; and
turning the pMOS FET OFF to program a state where a net polarization of a ferroelectric material of the ox-FeFET points toward an oxide channel of the ox-FeFET.

16. The method of claim 15, wherein the V_{G} that is applied to the top electrode terminal is greater than max(V_{th,n}, V_{TE}−|V_{th,p}|) where V_{th,n} is a threshold voltage of the nMOS FET and V_{th,p} is a threshold voltage of the pMOS FET, and wherein the V_{TE} applied to the top electrode terminal is greater than V_{th,n}.

17. The method of claim 14, further comprising:
turning the nMOS FET OFF; and
turning the pMOS FET ON to program a state where a net polarization of a ferroelectric material of the ox-FeFET points away from an oxide channel of the ox-FeFET.

18. The method of claim 17, wherein the V_{G} that is applied to the top electrode terminal is less than min(V_{th,n}, V_{TE}−|V_{th,p}|), and wherein the V_{TE} applied to the top electrode terminal is greater than |V_{th,p}|.

19. The method of claim 14, further comprising:
turning the nMOS FET ON; and
turning the pMOS FET ON to read information stored in the memory cell.

20. The method of claim 19, wherein V_{th,n}<V_{G}<V_{TE}−|V_{th,p}|, and wherein V_{TE}>V_{th,n}+|V_{th,p}|.
